(19) United States
(12) Patent Application Publication
(10) Pub. No.: US 2012/0025057 A1
(43) Pub. Date: Feb. 2, 2012

(54) Body- mounted portable viewing system for electronic devices

(76) Inventor: Jawad Sahloul, Dubai (AE)

(21) Appl. No.: 13/112,811

(22) Filed: May 20, 2011

Related U.S. Application Data
(60) Provisional application No. 61/395,993, filed on May 20, 2010.

(51) Int. Cl. H05K 7/00

(52) U.S. Cl. 248/688

(57) ABSTRACT

The present invention is an apparatus and method for holding portable electronic devices at a comfortable line of vision and adjustable for each user to enjoy reading or web browsing or any other use of these electronic devices. The invention will be mounted on the user's waist belt.

### BACKGROUND OF THE INVENTION

Portable electronic reading devices are slowly taking the place of regular books. Many features are being integrated into these devices such as the ability to browse the web or run different types of applications. The market is also witnessing a new category of portable computer devices represented in tablet pcs which has the ability to do what a laptop can do in addition to being light-weight and portable. The common way to hold these portable electronic devices is in the user's hand or place it in his/her lap when in seated position. The way the user holds these electronic devices may cause strain on the neck and other parts of the body such as shoulders and back. Also having these electronic devices in direct contact with the human body for long periods of time and placing them in one's lap close to genitals might have negative effects on human health. In conclusion, there is a need for a better way to hold such electronic devices others than the current way of holding it with one of the hands or laying it down on the lap.

The present invention is in the technical field of holders for portable electronic devices such as tablet pcs and electronic books.

More specifically, the present invention is in the technical field of holders mounted on the user's body.

### SUMMARY OF THE INVENTION

The present invention is an apparatus and method for holding portable electronic devices at a comfortable line of vision and adjustable for each user to enjoy reading or web browsing or any other use of these electronic devices. The invention will be mounted on the user's waist belt.

### BRIEF DESCRIPTION OF THE DRAWINGS

FIG. 1 is right side view of invention;

FIG. 2 is a front side view thereof;

FIG. 3 is a left side view thereof;

FIG. 4 is a top side view thereof;

FIG. 5 is a bottom view thereof;

FIG. 6 is a back elevation view thereof.

FIG. 7 is a close-up back view of the belt box of the invention;

FIG. 8 is a left view of the closed belt box of the invention;

FIG. 9 is a left view of the belt box of the invention when ajar;

FIG. 10 is a back elevation view of the electronic device sleeve of the invention;

FIG. 11 is a front elevation view of the electronic device sleeve of the invention;

FIG. 12 is the exploded view of the invention;

### SYSTEM DESCRIPTION

The system contains three main parts in addition to few optional parts:
1—Waist Box: This will be mounted on the user's belt. The box can be made of any solid material. The inside of the box will contain extendable arms.
2—Extendable Arms: within the box are the extendable arms which are telescopic tubes that the user can extend upward and pass through the loops on the back of the electronic device.
   Extendable legs: are optional telescopic tubes that get attached to the tablet and extend downward as support columns to help the main system with heavier electronic devices.
3—Loops: loops are half circular shape objects that get mounted the back of the electronic device or its protective sleeve. Loops create the space that the extended arm goes through in order to hold the electronic device. An optional custom made protective sleeve with built in loops could be made. The top loop which is the last loop for the extendable arm to go through will be closed on the top to prevent gravity from pulling the device down.

The invention is a hands free system to hold any electronic reading device or portable computer devices such as tablet pcs at a comfortable, adjustable level for the user to enjoy reading while his/her hands are free to do something else. The system accomplishes this beginning with a special base box mounted on to the user's belt. This box can be attached to the waist by having loops on the box where the belt would go through or by giving the box the ability to hook onto the user's belt. The box contains extendable arms that extend upward and angular to the user's body.

This is essentially an apparatus and method for holding portable electronic devices, comprising of a base in the shape of a box that can be mounted to a belt as a modified belt buckle or as an added accessory to a belt buckle. The box is mounted to the belt through slots on the back of the box that the belt can go through or via other methods. The box has an adjustable door hinge in the bottom of the box which faces the floor. On the sides of the box is the adjusting part of the hinge that controls the degree angle at which the user desires the door of the box to remain open which affects the angle the user can view the electronic device. A spring could be used to support the door and push it upward to reverse the effect that gravity has on the door. The box contains two extendable arms that can be lengthened upward. The arms are mounted on the inside of the box's door. The arms are hidden in the box when the box is closed and can only be seen when the user decides to open the door of the box and extend the arms up so the portable electronic device could be mounted for use.

The arms are normally composed of three or more telescoping sections similar to the opening process an antenna. The extendable arms can be lengthened or shortened at user's discretion. The arms reside in the belt box until the user desires to use the system. The user opens the door of the box which opens away from the user's body, chooses the angle at which he desires to view the device, and pulls the arms to the length that he desires. Finally, he mounts his electronic device with or without the viewing sleeve on by passing the arms through the special loops attached to the back of the device or its protective sleeve. Protective sleeves can also be designed with loops on its back as part of this system.

This invention accomplishes: better sitting posture for the user by providing custom viewing position for each user based on height and vision, portability of viewing device made possible by removable belt box (that can easily be modified for use as a belt buckle), viewing sleeve also serves as protection for the electronic device, better posture for reading electronic books and tablet pcs, hands free advantage since there will be no need to hold the device in hand which can also minimize any possible risk of direct exposure to heat and radiation omitted from the device. This invention can be used in more than one way such as: base belt box can be modified to be used in place of a belt buckle. The viewing sleeve provides protection for the electronic device.

Optional legs could be installed on the back of the viewing sleeve for added support which also can be used without the main belt box, on a table to prop the device for easy, hands-free viewing the manner.

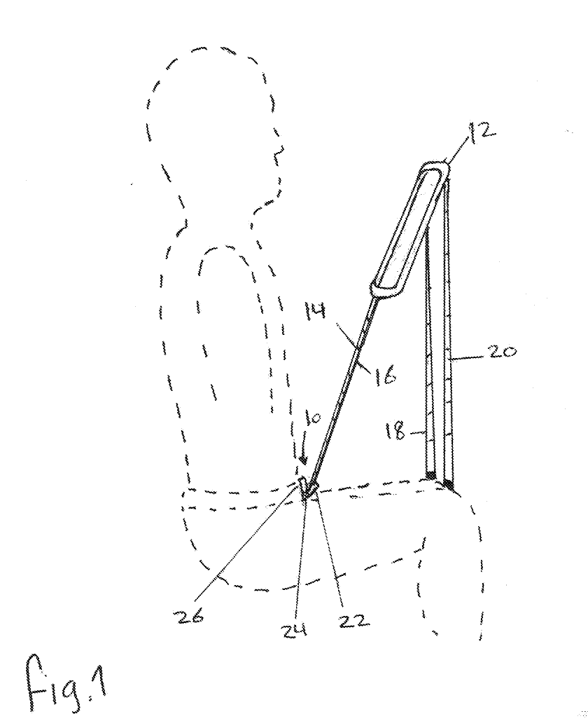

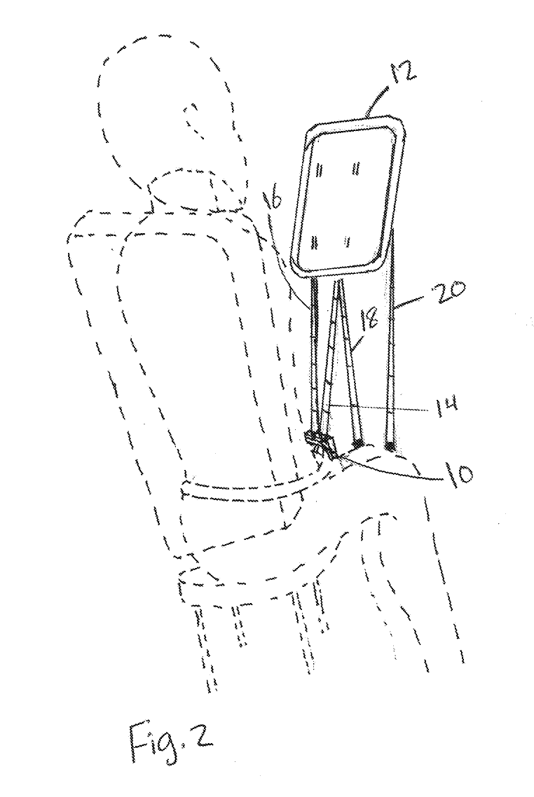

Referring now to the invention in more detail, in FIG. 1 and FIG. 2 there is shown a user seated on a chair while using the invention. The user has the belt box 10 (also could be easily modified to a belt buckle) mounted to the belt. Out of the belt box extends upward the two extendable arms, namely a first arm 14 and a second arm 16. The two arms 14 and 16 hold the electronic device sleeve 12 in front of the user for easy reading and browsing. Out of the sleeve 12, extend down two additional optional extendable legs, namely a first leg 18 and a second leg 20 for added support for heavier electronic devices. The two legs 18 and 20 could be supported on the user's legs or any surface they reach around the user for added support.

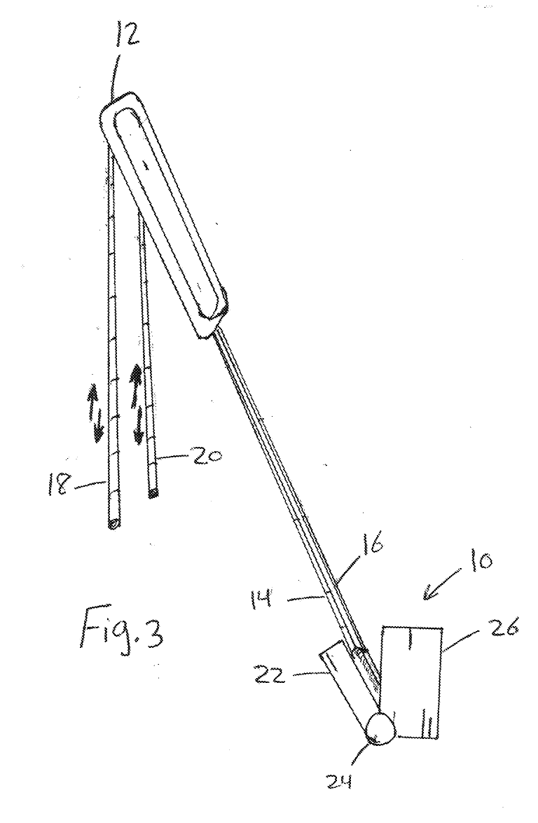

Referring now to FIG. 3 there is shown the invention from the left side with all the parts assembled, belt box 10, two arms 14 and 16, electronic device sleeve 12, and two legs 18, 20. Also it shows how the legs 18, 20 on the electronic device sleeve could extend up or down or to the sides. The right side view is an exact mirror image.

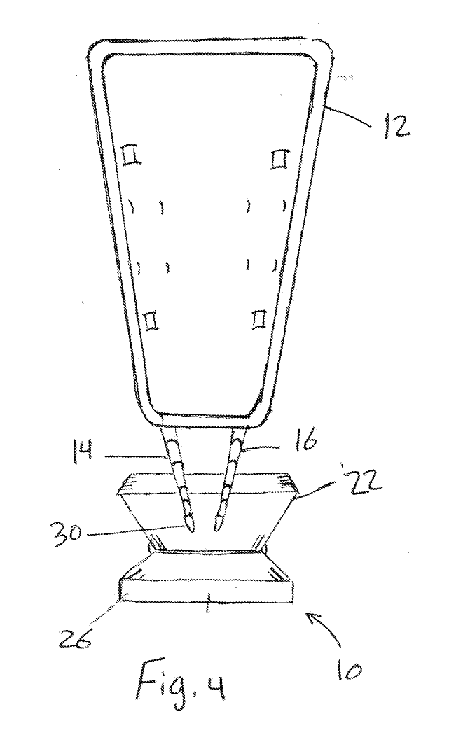

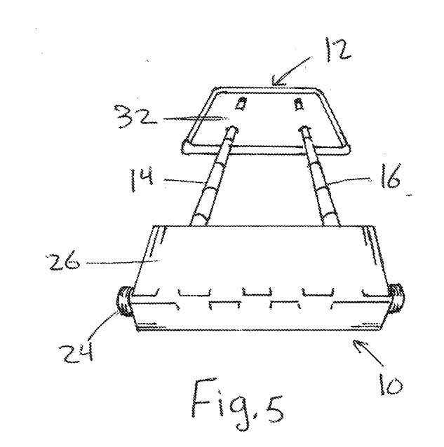

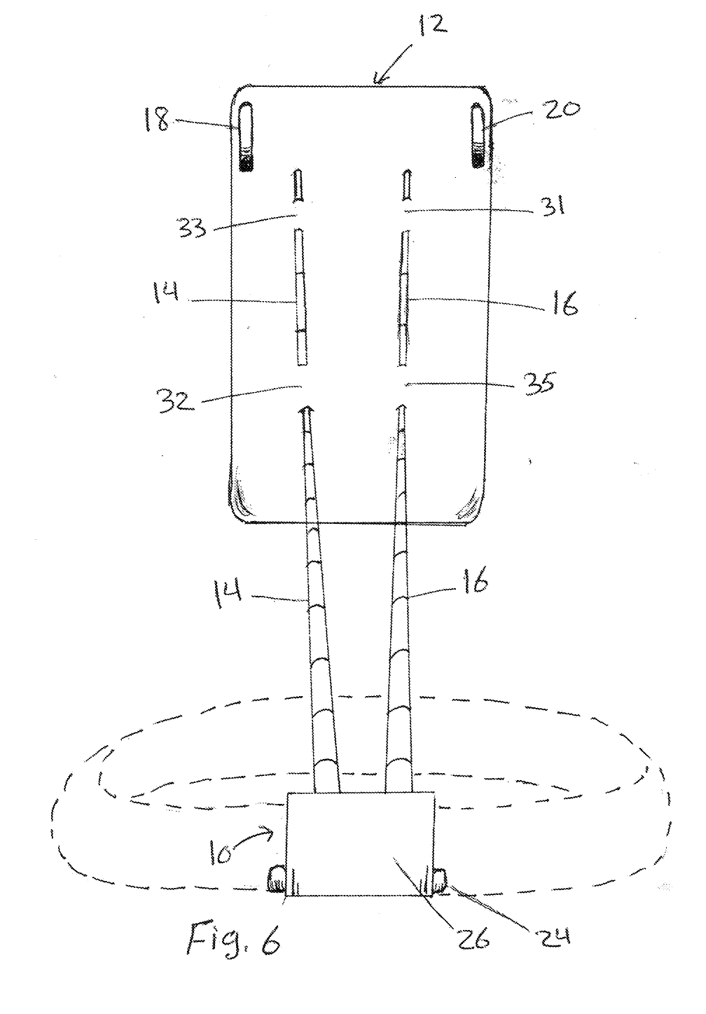

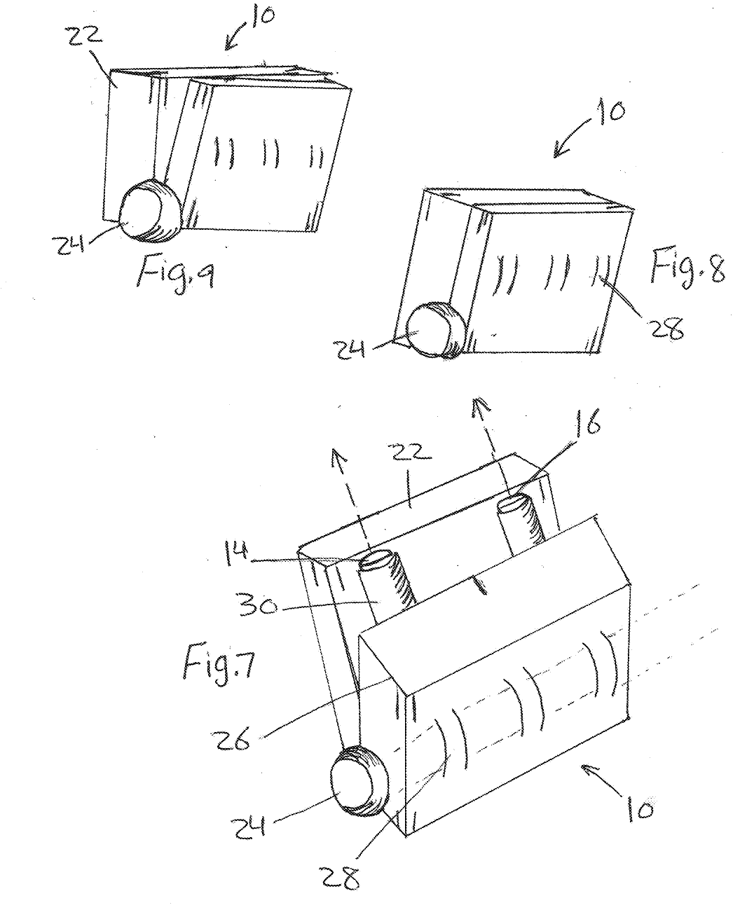

Referring now to FIG. 4 there is shown the invention from top over the user's head. The view shows the belt box 10 when opened. Further, it shows the two arms 14, 16 mounted and extended out of the box's door 22. Also it shows the front of the device sleeve 12. FIG. 4 also shows the back of the box that faces the user's body. Finally, it shows the base 30 for the extendable arms.

Referring now to FIG. 5 there is shown a bottom view of the invention. The view shows the bottom of the box 10. Further, it shows the box hinge and adjusting knobs 24. Also it shows the arms 14 and 16 extended upward and getting through the loops 32 on the back of the case 12. This FIG. 5 also shows the protective sleeve 12 for the electronic device.

Referring now to FIG. 6 there is shown an elevation back view of the invention. The view shows the back of the sleeve 12. It also shows the door of the box 26 and the adjusting door knob 24. This view shows the extendable arms 14, 16 and the loops 31, 32, 33, 35. This FIG. 6 also shows the extendable legs 18, 20 and the protective sleeve 12. In more details, it shows the belt box 10 would look like on the user's belt.

Referring now to FIG. 8 there is shown belt box 10 when closed which can remain on one of the users sides or substitute the belt buckle after few modifications or be used in a addition to the buckle after moving the buckle to the side so the box 10 could take the center position on the user's waist when the user decides to use the holder system.

Referring now to FIG. 9 and FIG. 7 which show the box 10 slightly open and it shows the hinge adjusting knob 24 and how the knob could control the angle degree of which the door 22 would open. Furthermore FIG. 7 shows the base 30 of the extendable arms 14, 16 when not extended.

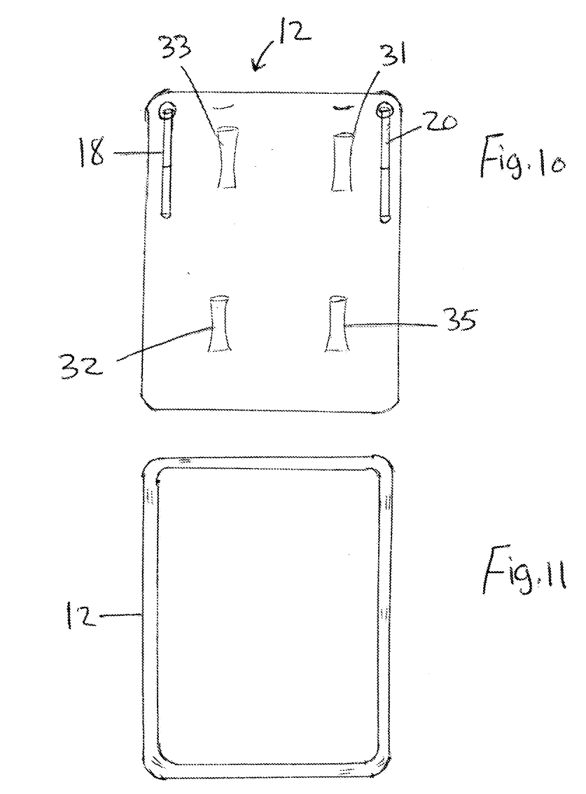

Referring now to FIG. 10 there is shown the back side of the sleeve 12. Also it shows the two extendable legs 18, 20. Also it shows loops 33, 31, 32, 35 where the arms 14, 16 would be held through on the back of the sleeve 12.

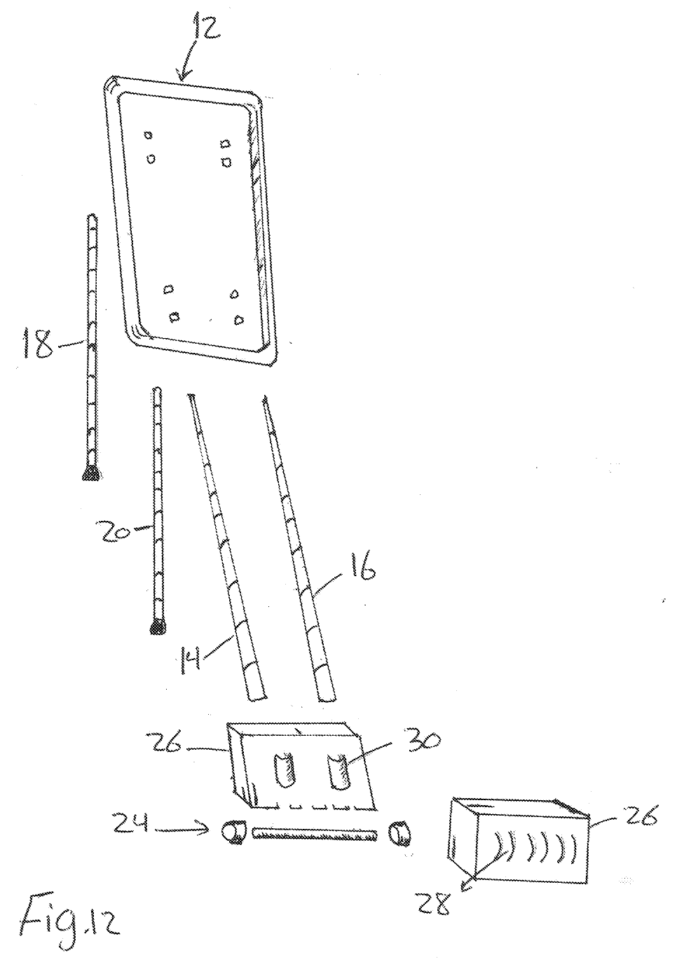

Referring now to FIG. 11 there is shown the front of the sleeve 12 where electronic device will be encased.

Referring now to FIG. 12 there is shown all the parts of the invention when disassembled: protective sleeve 12, extendable legs 18, 20, extendable arms 14, 16, belt box door 22, base 30 for extendable arms 14, 16, hinge adjusting knob 24, belt box loops 28, and back of the belt box 26.

I claim:

1. A method for holding a portable electronic device at a user's viewing level, comprising:
a. a base mounted on a belt which is fastened around a user's waist,
b. a base mounted on the portable electronic device,
c. a number of extendable support members connecting the two bases whereby said portable electronic device will be supported at a comfortable line of vision for the user.
